(19) United States
(12) Patent Application Publication
(10) Pub. No.: US 2005/0218933 A1
(43) Pub. Date: Oct. 6, 2005

(54) CMOS buffer with hysteresis

(75) Inventors: David L. Linam, Ft. Collins, CO (US); Guy H. Humphrey, Ft. Collins, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(73) Assignee: Agilent Technologies, Inc., Loveland, CO (US)

(21) Appl. No.: 10/817,668

(22) Filed: Apr. 2, 2004

(51) Int. Cl. H03K 19/0175

(52) U.S. Cl. 326/83

(57) ABSTRACT

A CMOS buffer with hysteresis is implemented. In one embodiment, an upper-trip circuit (102) and a lower-trip circuit (104) are implemented with CMOS inverters. The upper-trip circuit (102) and the lower-trip circuit (104) provides output to a pull-up device (110) and a pull-down device (111), respectively. The pull-up device (110) and the pull-down device (111) both generate an output signal onto a net (112). A bus holder (114) is coupled to the net (112) and maintains the output signal. In addition, an output circuit (116) is coupled to the net (112) and processes the output signal. In one embodiment, the output circuit is implemented with a CMOS buffer and functions as a buffer with hysteresis. In another embodiment, the output circuit is implemented with an inverter and functions as an inverting buffer with hysteresis. In a third embodiment, the output circuit is implemented with a connection (i.e., signal conveyance) and functions as a non-inverting buffer with hysteresis.

### FIELD OF THE INVENTION

This invention relates to electronics systems. Specifically, the present invention relates to electronic circuits.

### DESCRIPTION OF THE RELATED ART

Digital electronics are in wide-scale use in many industries. In most digital electronic systems, noise adversely effects the operation of the digital electronics. For example, signals are often characterized by a rising and falling transition. The rising or falling transitions may have dips or may not monotonically increase or decrease. The dips in the signal or the lack of symmetry are typically used to represent noise in the signal. When a signal with noise is applied to a digital circuit, the noise may cause the circuit to produce rapid changes on the output before the final value on the output stabilizes.

One specific type of electronic circuit is a buffer. A CMOS buffer circuit is composed of two CMOS inverters positioned in series. Each inverter includes an n-type device and a p-type device. A noisy signal on the input of a CMOS inverter can have adverse effects on the output of the CMOS inverter. For example, a noisy signal on the input of a CMOS buffer may change the output of the CMOS buffer from a zero to a one and then back from a one to a zero. Ultimately, this would cause a substantial problem in a circuit that implements the CMOS buffer because incorrect values may be propagated through the circuit.

Thus, there is a need for a method and apparatus for managing noise in electronic circuits. There is a need for a method and apparatus for controlling the effect of noise on a buffer circuit. There is a need for a method and apparatus for controlling the effect of noise in a CMOS inverter.

A buffer comprises an input conveying a first signal; an upper trip circuit coupled to the input and generating a second signal in response to the first signal conveyed by the input; a lower trip circuit coupled to the input and generating a third signal in response to the first signal; a net conveying a high voltage signal and a low voltage signal; a pull-up device coupled between the upper trip circuit and the net, the pull-up device generating the high voltage signal in response to the second signal; a pull-down device coupled to the lower trip circuit and coupled to the net, the pull-down device generating the low voltage signal in response to the third signal; a bus holder coupled to the net, the bus holder capable of holding the high voltage signal on the net and capable of holding the low voltage signal on the net; and an output coupled to the net, the output processing the high voltage signal and the low voltage signal.

A CMOS buffer comprises an input conveying an input signal; a first CMOS inverter coupled to the input and generating a first signal in response to the input signal conveyed by the input; a second CMOS inverter coupled to the input and generating a second signal in response to the input signal; a pfet coupled to the first CMOS inverter and generating a third signal in response to the second signal generated by the first CMOS inverter; an nfet coupled to the second CMOS inverter and generating a fourth signal in response to the third signal generated by the second CMOS inverter; a net coupled to the pfet and coupled to the nfet, the net capable of conveying the third signal and capable of conveying the fourth signal; a storage node coupled to the net, the storage node capable of maintaining the third signal on the net and capable of maintaining the fourth signal on the net; and an output coupled to the net, the output processing the third signal and the fourth signal.

A buffer comprises an input conveying a first signal; an upper threshold circuit coupled to the input and generating a second signal in response to the first signal hitting an upper threshold; a lower threshold circuit coupled to the input and generating a third signal in response to the first signal hitting a lower threshold; a conveyance coupled to the upper threshold circuit and coupled to the low threshold circuit, the conveyance capable of conveying a high voltage signal and capable of conveying a low voltage signal; a high voltage circuit coupled to the upper threshold circuit and coupled to the conveyance, the high voltage circuit causing the high voltage signal on the conveyance; and a low voltage circuit coupled to the low threshold circuit and coupled to the conveyance, the low voltage circuit causing the low voltage signal on the conveyance.

### SUMMARY OF THE INVENTION

In one embodiment, a CMOS buffer circuit with hysteresis is implemented. A CMOS buffer is implemented with two trip points. One trip point is used to define an upper-threshold value. A second trip point is used to define a lower-threshold value.

In one embodiment, the two trip points are implemented with two CMOS inverters. The output of the first inverter serves as the input for a pull-up device and the output of the second inverter serves as the input for a pull-down device. The pull-up device and the pull-down device are connected to a net. Both the pull-up device and the pull-down device output (i.e., drive) a signal onto the net. An output is in series with the net and processes the output from the pull-up device and the pull-down device. A bus holder is also connected to the net and maintains the signal on the net.

In one embodiment, a rising transition or a falling transition is applied to an input. The rising or falling transition is processed through trip circuits. In a hysteresis circuit, the upper-trip circuit is implemented with a threshold value that is different from the lower-trip circuit. For example, in one embodiment, the threshold value in the upper-trip circuit is at a higher voltage level than the threshold value of the lower-trip circuit.

In one embodiment, the upper-trip circuit is implemented with a CMOS inverter. The CMOS inverter in the upper-trip circuit includes a pfet and an nfet. In addition, the lower-trip circuit is implemented with a CMOS inverter. The CMOS inverter in the lower-trip circuit includes a pfet and an nfet. In both the upper-trip circuit and the lower-trip circuit, the ratio of the size of the pfet to the nfet defines the threshold value of the trip circuit (i.e., upper-trip circuit, lower-trip circuit).

In one embodiment, the upper-trip circuit provides an input to a pull-up device and the lower-trip circuit provides an input to a pull-down device. The pull-up and pull-down devices both drive a net. A bus holder is connected to the net. The bus holder maintains the signal on the net.

### BRIEF DESCRIPTION OF THE DRAWINGS

FIG. 1 displays a block diagram depiction of a circuit implemented in accordance with the teachings of the present invention.

FIG. 2 displays an embodiment of a buffer with hysteresis implemented in accordance with the teachings of the present invention.

FIG. 3 displays an embodiment of an inverting buffer with hysteresis implemented in accordance with the teachings of the present invention.

FIG. 4 displays an inverting buffer with hysteresis implemented in accordance with the teachings of the present invention.

FIG. 5 displays a non-inverting buffer with hysteresis implemented in accordance with the teachings of the present invention.

### DESCRIPTION OF THE INVENTION

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

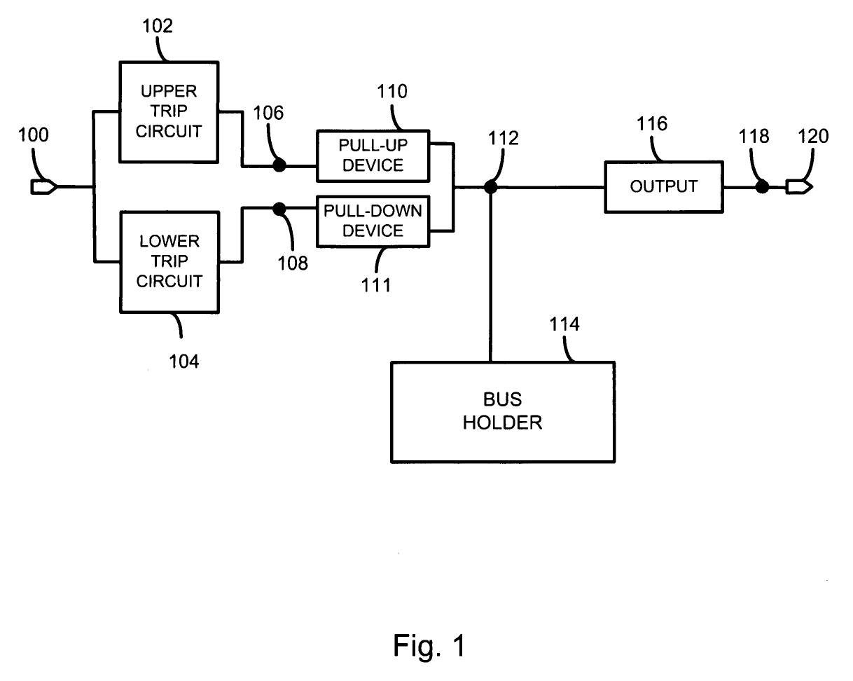

FIG. 1 displays one embodiment of the present invention. FIG. 1 displays a block diagram depiction of a circuit implemented in accordance with the teachings of the present invention. In FIG. 1, an input signal is applied to input 100. The input signal may have a rising transition or a falling transition. An upper-trip circuit 102 is connected between the input 100 and a net 106. A lower-trip circuit 104 is connected between the input 100 and a net 108. In one embodiment, the combination of the upper-trip circuit 102 and the lower-trip circuit 104 may be considered a hysteresis circuit.

In one embodiment, the upper-trip circuit 102 is any CMOS circuit that changes state when the input signal applied to input 100 passes above or below a threshold established in the upper-trip circuit 102. In one embodiment, the lower-trip circuit 104 is any CMOS circuit that changes state when the input signal applied to input 100 passes above or below a threshold established in the lower-trip circuit 104. In one embodiment, the threshold established in the upper-trip circuit 102 is above the threshold established in the lower-trip circuit 104.

A net 106 is in series with the upper-trip circuit 102. The net 108 is in series with the lower-trip circuit 104. A pull-up device 110 is connected between net 106 and a net 112. A pull-down device 111 is connected between the net 108 and the net 112. Net 106 transports a signal that serves as input (i.e., drives) to the pull-up device 110. Net 108 transports a signal that serves as input (i.e., drives) the pull-down device 111. The pull-up device 110 and the pull-down device 111 each produce an output signal that is conveyed on the net 112.

In one embodiment, bus holder 114 is connected to net 112. Bus holder 114 is any CMOS circuit that maintains the state on net 112. An output 116 is in series with net 112, an output net 118 is in series with output 116, and an output node 120 is in series with output net 118.

In one embodiment of the present invention, pull-up device 110 and pull-down device 111 are each implemented with CMOS technology. In one embodiment, pull-up device 110 is a device that pulls up the voltage on net 112 to overdrive the bus holder 114. In one embodiment, pull-down device 111 is a device that pulls down the voltage on net 112 to overdrive the bus holder 114.

During operation, a rising or falling input signal may be applied to input 100. The rising signal may increase beyond a threshold (i.e., trip point) established by the lower-trip circuit 104 and the upper-trip circuit 102. In the alternative, a falling signal may decrease beyond a threshold (i.e., trip point) established by the upper-trip circuit 102 and the lower-trip circuit 104. When the threshold is reached in the upper-trip circuit 102 or the lower-trip circuit 104, the upper-trip circuit 102 or the lower-trip circuit 104 changes state (i.e., output—zero to one or one to zero).

A change in the output of the upper-trip circuit 102 results in a change in the state of the net 106. A change in the state of the output of the lower-trip circuit 104 results in a change in the state of the net 108. The net 106 transports a signal that provides an input to pull-up device 110 and the net 108 transports a signal that provides an input to pull-down device 111.

In one embodiment, bus holder 114 functions as a storage node. The bus holder 114 holds the value of a bus either high or low when no device (i.e., pull-up device 110 or pull-down device 111) is driving net 112. Therefore, the bus holder 114 will hold the value of the net 112 until the pull-up device 110 or the pull-down device 111 drives the net 112 to a different value. In one embodiment, the bus holder is implemented with back-to-back inverters.

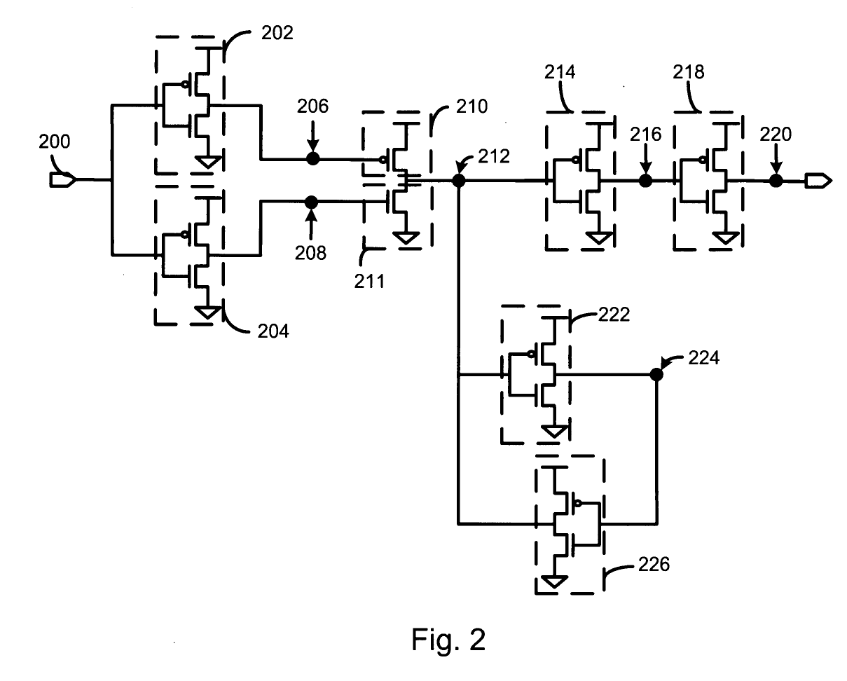

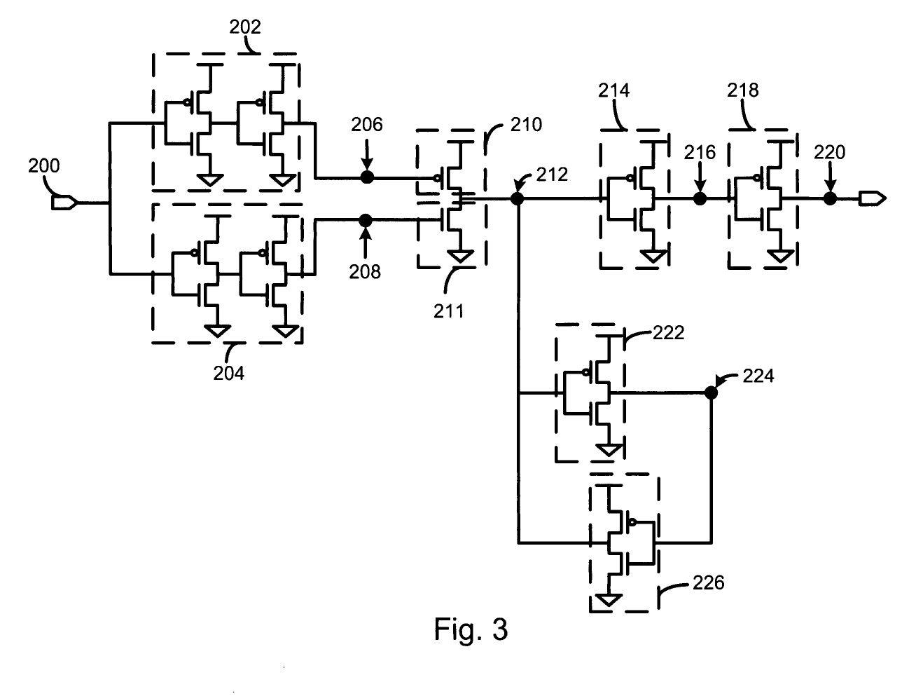

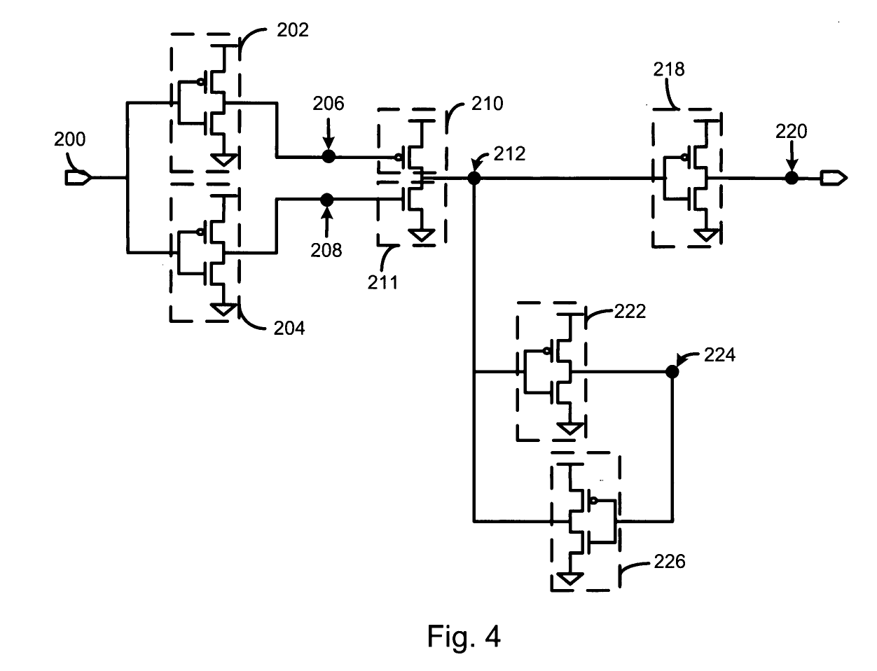

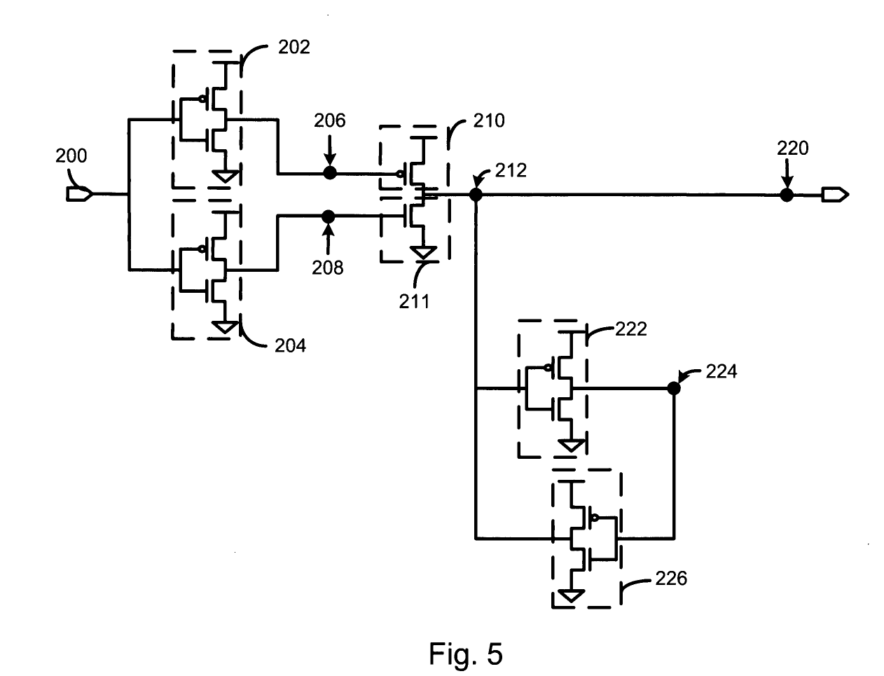

The output 116 is in series with the net 112. In one embodiment, the output 116 is implemented with two inverters, such as CMOS inverters, and functions as a buffer. The circuit of FIGS. 2 and 3 provide embodiments of this configuration. For the purposes of discussion, the circuit of FIG. 2 is labeled as a buffer with hysteresis. In a second embodiment, FIG. 3 is labeled an inverting buffer with hysteresis. In a third embodiment, the output 116 is implemented with a single inverter. The circuit of FIG. 4 is one embodiment of this configuration. For the purposes of discussion, the circuit of FIG. 4 is labeled an inverting buffer with hysteresis. In a fourth embodiment, the output 116 is implemented as a connection without any inverting circuits. The circuit of FIG. 5 is one embodiment of this configuration. For the purposes of discussion, the circuit of FIG. 5 is labeled a non-inverting buffer with hysteresis. The non-inverting buffer with hysteresis may be used to provide a signal for another device that takes a digital input, such as an inverter, a logic gate, a multiplexer, a register, etc.

FIG. 2 displays an embodiment of a buffer with hysteresis implemented in accordance with the teachings of the present invention. FIG. 2 provides a detailed embodiment of the CMOS buffer with hysteresis. In FIG. 2, the upper-trip circuit 102 of FIG. 1 is implemented with inverter 202. The lower-trip circuit 104 of FIG. 1 is implemented with inverter 204. Nets 106, 108, 112, and 118 of FIG. 1 correspond to nets 206, 208, 212, and 220 of FIG. 2. The pull-up device 110 is implemented with pfet 210. The pull-down device 111 is implemented with nfet 211. The output 116 of FIG. 1 is implemented with inverter 214, net 216, and inverter 218 of FIG. 2. Bus holder 114 of FIG. 1 is implemented with inverter 222, inverter 226, and net 224 of FIG. 2.

In FIG. 2, an input is provided at node 200. Node 200 is connected to the inputs of inverter 202 and inverter 204. The inverter 202 is connected between node 200 and a net 206. In one embodiment, node 200 is connected on the input of inverter 202 and net 206 is connected to the output of inverter 202. The inverter 204 is connected between node 200 and net 208. In one embodiment, node 200 is connected to the input of inverter 204 and net 208 is connected to the output of inverter 204. Pfet 210 is connected between net 206 and net 212. Nfet 211 is connected between net 208 and net 212. The pfet 210 and the nfet 211 each output a signal onto net 212.

Inverter 214 is connected between net 212 and a net 216. In one embodiment, net 212 is connected to the input of inverter 214 and net 216 is connected to the output of inverter 214. Inverter 214 is in series with inverter 218. Inverter 218 is connected between net 216 and an output net 220. In one embodiment, net 216 is connected to the input of inverter 218 and net 220 is connected to the output of inverter 218.

Inverter 222 is connected between net 212 and a net 224. In one embodiment, net 212 is connected to the input of inverter 222 and net 224 is connected to the output of inverter 222. Inverter 226 is connected between net 224 and net 212. In one embodiment, net 224 is connected to the input of inverter 226 and net 212 is connected to the output of inverter 226.

During operation of the CMOS buffer with hysteresis (i.e., FIG. 2), a signal is applied to input node 200. In one embodiment, a rising transition is applied to input node 200. In one embodiment, when a rising transition is applied to input node 200, input node 200 starts at zero voltage, nets 206 and 208 start at VDD. Net 212 also starts at zero voltage and net 224 starts at VDD. Lastly, output net 220 starts at zero voltage. In one embodiment, the size ratio of the pfet to nfet in inverter 202 is larger than the size ratio of the pfet to nfet in inverter 204. As a result, the trip point of inverter 202 is a higher voltage than the trip point of inverter 204. Consequently, inverter 202 controls the higher-trip point of the CMOS buffer with hysteresis depicted in FIG. 2 and inverter 204 controls the lower-trip point.

In one embodiment, the threshold voltages are separated and the amount of hysteresis is a function of the difference between the voltages. In some IC processes, there may be a fairly large difference between the threshold voltage of the pfet and the threshold voltage of the nfet. As an example, given that the gate lengths of the FETs in inverter 202 and the gate lengths of the FETs in inverter 204 are equal, the width ratio of inverter 202 may be 8:1 and the width ratio of inverter 202 may be 1:1.

In one embodiment, the trip point for inverter 202 is a higher voltage than the trip point for inverter 204. When the input signal applied to node 200 starts to transition from zero to VDD, the first voltage that the input signal will reach is the trip point for inverter 204, since inverter 204 is the lower voltage. When the input signal 200 reaches the lower voltage, then the net 208 will transition from one to zero. When the net 208 transitions from one to zero, the transition will turn off the nfet 211 (i.e., pull-down device). In this state, both the pfet 210 and the nfet 211 are off. The storage node (i.e., bus holder) consisting of inverter 222 and inverter 226 keep the value of net 212 at zero.

The input signal applied to node 200 continues to rise until it hits the trip point of inverter 202. When the input signal applied at node 200 hits the trip point of inverter 202, the net 206 transitions from a one to a zero. The transition of the net 206 from a one to a zero turns the pfet 210 on. As a result, the nfet 211 is off, the pfet 210 is on, and both nets 206 and 208 have transitioned to zero.

In one embodiment, inverter 226 is a weak inverter compared to pfet 210, therefore inverter 226 attempts to drive a zero onto net 212, but since pfet 210 is much stronger than inverter 226, the pfet 210 will overdrive the nfet of inverter 226. Ultimately, pfet 210 will transition net 212 from zero to one. The transition of net 212 from a zero to a one causes inverter 222 to change states, as a result, the net 224 changes from a one to a zero. Consequently, inverter 226 drives a one just like pfet 210. When net 212 transitions, a transition is made to the output net 220, through inverter 214, net 216, and inverter 218.

The inverse transition of the input signal produces the compliment of the foregoing procedure. In the inverse transition, the input signal applied to node 200 is at VDD, net 206 is at zero, net 208 is at zero, net 212 is at VDD, output net 220 is at VDD, and net 224 is at zero. When the input signal applied to node 200 starts a falling transition, the first voltage that the signal encounters is the trip voltage maintained by the higher voltage threshold inverter 202. When the input signal passes the higher voltage, which causes the net 206 to transition from a zero to one, net 206 transitioning from a zero to a one turns off the pfet 210. As a result, both the nfet 211 and the pfet 210 are off. However, the voltage at net 212 is being held by the storage node, which consists of inverter 222 and inverter 226. The voltage on the input node 200 continues to fall and then the input signal applied at node 200 hits the trip point (i.e., threshold) of inverter 204, which causes the net 208 to transition from zero to VDD. The transition on net 208 from zero to VDD turns on the nfet 211.

The nfet 211 is sized to be stronger than the pfet of inverter 226. As a result, the nfet 211 pulls the voltage of net 212 down to zero, which causes inverter 222 to change states. Net 224 changes from zero to one. As a result, nfet 211 and inverter 226 both drive the same value onto net 212.

The transition on net 212 propagates to the output net 220. Inverter 214 inverts the transition. As a result, net 216 has the compliment of the signal on net 212. In a similar manner, inverter 218 generates the compliment of the signal on net 216 onto the output net 220.

The drive capability of the pfet of inverter 214 as compared to the drive capability of the nfet of inverter 226 is a function of the process variation. In one embodiment, the pfet 210 in the slow case is stronger than the nfet of inverter 226 in the fast case. If the process variation is 2:1, the relative strength between the two inverters is on the order of 4:1. Since pfets are typically weaker than nfets of the same size, this must also be taken into account. It should be appreciated that although specific ratios have been defined and discussed, a large range of ratios between devices and device sizes are contemplated and within the scope of the present invention.

FIG. 3 displays an embodiment of an inverting buffer with hysteresis implemented in accordance with the teachings of the present invention. In FIG. 3, the upper-trip circuit 102 of FIG. 1 is implemented with buffer 202. The lower-trip circuit 104 of FIG. 1 is implemented with buffer 204 of FIG. 3. Nets 106, 108, 112, and 118 of FIG. 1 correspond to nets 206, 208, 212, and 220 of FIG. 3. The pull-up device 110 of FIG. 1 is implemented with pfet 210 of FIG. 3. The pull-down device 111 is implemented with nfet 211 of FIG. 3. The output 116 of FIG. 1 is implemented with inverter 214, net 216, and inverter 218 of FIG. 3. Bus holder 114 of FIG. 1 is implemented with inverter 222, inverter 226, and net 224 of FIG. 3.

In FIG. 3, an input is provided at node 200. Buffer 202 is connected between input node 200 and a net 206. In one embodiment, input node 200 is connected to the input of the buffer 202 and net 206 is connected to the output of the buffer 202. Buffer 204 is connected between input node 200 and a net 208. In one embodiment, input node 200 is connected to the input of the buffer 204 and net 208 is connected to the output of the buffer 204. Buffer 202 is in series with net 206 and buffer 204 is in series with net 208. Pfet 210 is connected between net 206 and a net 212. In one embodiment, net 206 is connected to the input of pfet 210 and net 212 is connected to the output of pfet 210. Nfet 211 is connected between net 208 and the net 212. In one embodiment, net 208 is connected to the input of nfet 211 and net 212 is connected to the output of nfet 211. The pfet 210 and the nfet 211 each output a signal onto net 212.

Inverter 214 is connected between net 212 and net 216. In one embodiment, net 212 is connected to the input of inverter 214 and net 216 is connected to the output of inverter 214. Inverter 218 is connected between net 216 and a net 220. In one embodiment, net 216 is connected to the input of inverter 218 and net 220 is connected to the output of inverter 218.

Inverter 222 is connected between net 212 and net 224. In one embodiment, net 212 is connected to the input of inverter 222 and net 224 is connected to the output of inverter 222. Inverter 226 is connected between net 224 and net 212. In one embodiment, net 224 is connected to the input of inverter 226 and net 212 is connected to the output of inverter 226.

During operation of the inverting buffer with hysteresis (i.e., FIG. 3), a signal is applied to input node 200. In one embodiment, a rising transition is applied to input node 200. In one embodiment, when a rising transition is applied to input node 200, input node 200 starts at zero voltage, nets 206 and 208 start at zero. Net 212 starts at VDD and net 224 starts at zero. Lastly output 220 starts at VDD.

In one embodiment, the size ratio of the pfet to nfet in the first inverter in buffer 202 is smaller than the size ratio of the pfet to nfet in first inverter in buffer 204. As a result, the trip point of buffer 202 is a lower voltage than the trip point of buffer 204. Consequently, buffer 202 controls the lower-trip point of the inverting buffer with hysteresis depicted in FIG. 3 and buffer 204 controls the higher-trip point.

In one embodiment, the trip point for buffer 202 is a lower voltage than the trip point for buffer 204. When the input signal applied to node 200 starts to transition, the first voltage that the input signal will reach is the trip point for buffer 202, since buffer 202 is the lower voltage. When the input signal 200 reaches the lower voltage, then the net 206 will transition from zero to one. When the net 206 transitions from zero to one, which will turn off the pfet 210 (i.e., pull-up device) both the pfet 210 and the nfet 211 are off. The storage node (i.e., bus holder) consisting of inverter 222 and inverter 226 maintain the value on net 212 at VDD.

The input signal applied to node 200 continues to rise until it hits the trip point of buffer 204. When the input signal input at node 200 hits the trip point of buffer 204, the net 208 transitions from a zero to a one. The transition of the net 208 from a zero to a one turns the nfet 211 on. As a result, the nfet 211 is on, the pfet 210 is off, and both nets 206 and 208 have transitioned to one.

In one embodiment, inverter 226 is a weak inverter compared to nfet 211, therefore inverter 226 attempts to drive a one onto net 212, but since nfet 211 is much stronger than inverter 226, the nfet 211 will overdrive the pfet of inverter 226. Ultimately, nfet 211 will transition net 212 from one to zero. The transition of net 212 from a one to a zero causes inverter 222 to change states, as a result, the net 224 changes from a zero to a one. Consequently, inverter 226 drives a zero just like nfet 211. When net 212 transitions, a transition is made to the output net 220 through inverter 214, net 216, and inverter 218.

The inverse transition of the input signal produces the compliment of the foregoing procedure. In the inverse transition, the input signal applied to node 200 is at VDD, net 206 is at VDD, net 208 is at VDD, net 212 is at zero, output net 220 is at zero, and net 224 is at VDD. When the input signal applied to node 200 starts a falling transition, the first voltage that the signal encounters is the voltage maintained by the higher voltage threshold buffer 204. When the input signal passes the higher voltage, which causes the net 208 to transition from a one to zero the nfet 211 turns off. As a result, both the nfet 211 and the pfet 210 are off. The voltage at net 212 is held by the storage node, which consists of inverter 222 and inverter 226. The voltage on the input node 200 continues to fall and then the input signal applied at node 200 hits the trip point (i.e., threshold) of buffer 202, which causes the net 206 to transition from one to zero. The transition on net 206 from one to zero turns on the pfet 210.

The pfet 210 is sized to be stronger than the nfet of inverter 226. As a result, the pfet 210 pulls the voltage of net 212 up to VDD, which causes inverter 222 to change states. Net 224 changes from one to zero. As a result, pfet 210 and inverter 226 both drive the same value onto net 212.

The transition on 212 propagates to the output net 220. Inverter 214 inverts the transition. As a result, net 216 has the compliment of the signal on net 212. In a similar manner, inverter 218 transports the compliment of the signal on net 216 onto the output net 220.

FIG. 4 displays an inverting buffer with hysteresis implemented in accordance with the teachings of the present invention. In FIG. 4, the upper-trip circuit 102 of FIG. 1 is implemented with inverter 202. The lower-trip circuit 104 of FIG. 1 is implemented with inverter 204 of FIG. 4. Nets 106, 108, 112, and 118 of FIG. 1 correspond to nets 206, 208, 212, and 220 of FIG. 4. The pull-up device of FIG. 1 is implemented with pfet 210 of FIG. 4. The pull-down device of FIG. 1 is implemented with nfet 211 of FIG. 4. The output 116 of FIG. 1 is implemented with inverter 218 of FIG. 4. Bus holder 114 of FIG. 1 is implemented with inverter 222, inverter 226, and net 224 of FIG. 4.

In FIG. 4, an input node is shown as 200. The inverter 202 is connected between the input node 200 and a net 206. In one embodiment, the input node 200 is connected to the input of inverter 202 and the net 206 is connected to the output of inverter 202. The inverter 204 is connected between the input node 200 and a net 208. In one embodiment, input node 200 is connected to the input of inverter 204 and net 208 is connected to the output of inverter 204. Net 206 is in series with inverter 202. Net 208 is in series with inverter 204. Pfet 210 is connected between net 206 and net 212. In one embodiment, net 206 is connected to the input of pfet 210 and net 212 is connected to the output of pfet 210. Nfet 211 is connected between net 208 and net 212. In one embodiment, net 208 is connected to the input of nfet 211 and net 212 is connected to the output of nfet 211. Pfet 210 and nfet 211 each output signals to (i.e., drive) net 212.

Inverter 222 is connected between net 212 and net 224. In one embodiment, net 212 is connected to the input of inverter 222 and net 224 is connected to the output of inverter 222. Inverter 226 is connected between net 224 and net 212. In one embodiment, net 224 is connected to the input of inverter 226 and net 212 is connected to the output of inverter 226.

During operation of the inverting buffer with hysteresis (i.e., FIG. 4), a signal is applied to input node 200. In one embodiment, a rising transition is applied to input node 200. In one embodiment, when a rising transition is applied to input node 200, input node 200 starts at zero voltage, nets 206 and 208 start at VDD. Net 212 also starts at zero voltage and net 224 starts at VDD. Lastly, output net 220 starts at VDD. In one embodiment, the size ratio of the pfet to nfet in inverter 202 is larger than the size ratio of the pfet to nfet in inverter 204. As a result, the trip point of inverter 202 would be at a higher voltage than the trip point of inverter 204. Consequently, inverter 202 controls the higher-trip point of the inverting buffer with hysteresis depicted in FIG. 4 and inverter 204 controls the lower-trip point.

In one embodiment, the trip point for inverter 202 is a higher voltage than the trip point for inverter 204. When the input signal applied at input node 200 starts to transition, the first voltage that input signal will reach is the trip point for inverter 204, since inverter 204 is the lower voltage. When the input signal 200 reaches the lower voltage, then the net 208 will transition from one to zero. When the net 208 transitions from one to zero, which will turn off the nfet 210, both the pfet 210 and the nfet 211 are off. The storage node (i.e., bus holder) consisting of inverter 222 and inverter 226 keeps the value of net 212 at zero.

As the input signal applied at input node 200 continues to rise, it hits the trip point of inverter 202. When the input signal applied at input node 200 hits the trip point of inverter 202, the net 206 transitions from a one to a zero. The transition of the net 206 from a one to a zero turns the pfet 210 on. As a result, the nfet 211 is off, the pfet 210 is on, and both nets 206 and 208 have transitioned to zero.

In one embodiment, inverter 226 is a weak inverter compared to pfet 210, therefore inverter 226 attempts to drive a zero, but since pfet 210 is much stronger than inverter 226, the pfet 210 will overdrive the nfet of inverter 226. Ultimately, the pfet 210 will transition net 212 from zero to one. The transition of net 212 from a zero to a one causes inverter 222 to change states. The net 224 changes from a one to a zero. As a result, inverter 226 drives a one just like pfet 210. When net 212 transitions, a transition is made to the output net 220 through inverter 218.

The inverse transition of the input signal produces the compliment of the foregoing procedure. In the inverse transition, the input signal is applied to input node 200 is at VDD, net 206 is at zero, net 208 is at zero, net 212 is at VDD, output net 220 is at zero, and net 224 is at zero. When the input signal applied to input node 200 starts a falling transition, the first voltage that the signal encounters is the voltage maintained by the higher voltage threshold inverter 202. When the input signal passes the higher voltage, which causes the net 206 to transition from a zero to one. Transitioning from a zero to a one turns off the pfet 210. As a result, both the nfet 211 and the pfet 210 are off. However, the voltage at net 212 is being held by the storage node (i.e., bus holder), which consists of inverter 222 and inverter 226. The voltage on the input continues to fall and then the input signal applied to input node 200 hits the trip point (i.e., threshold) of inverter 204, which causes the net 208 to transition from zero to VDD. The transition on net 208 from zero to VDD turns on the nfet 211.

The nfet 211 is much stronger than the pfet of inverter 226. As a result, the nfet 211 pulls the voltage of net 212 down to zero, which causes inverter 222 to change states. Net 224 changes from zero to one. As a result, nfet 211 and inverter 226 both drive the same value on net 212. The transition on net 212 propagates to the output net 220. Inverter 218 generates the compliment of the signal on net 212 onto the output net 220.

FIG. 5 displays a non-inverting buffer with hysteresis implemented in accordance with the teachings of the present invention. In FIG. 5, the upper-trip circuit 102 of FIG. 1 is implemented with inverter 202. The lower-trip circuit 104 of FIG. 1 is implemented with inverter 204 of FIG. 5. Nets 106, 108, 112, and 118 of FIG. 1 correspond to nets 206, 208, 212, and 220 of FIG. 5. The pull-up device 110 of FIG. 1 is implemented with pfet 210 of FIG. 5. The pull-down device 111 of FIG. 1 is implemented with nfet 211 of FIG. 5. The output 116 of FIG. 1 is implemented with node 220 of FIG. 5. Bus holder 114 of FIG. 1 is implemented with inverter 222, inverter 226 and net 224 of FIG. 5.

In FIG. 5, an input is applied to input node 200. Inverter 202 is connected between input node 200 and a net 206. In one embodiment, input node 200 is connected to the input of inverter 202 and net 206 is connected to the output of inverter 202. Inverter 204 is connected between input node 200 and a net 208. In one embodiment, input node 200 is connected to the input of inverter 204 and net 208 is connected to the output of inverter 202. Pfet 210 is in series with net 206. Nfet 211 is in series with net 208. Pfet 210 is connected between net 206 and a net 212. In one embodiment, net 206 is connected to the input of pfet 210 and net 212 is connected to the output of pfet 210. Nfet 211 is connected between net 208 and a net 212. In one embodiment, net 208 is connected to the input of nfet 211 and net 212 is connected to the output of nfet 211.

A net 212 conveys a signal output by pfet 210 or nfet 211. Inverter 222 is connected between net 212 and net 224. In one embodiment, net 212 is connected to the input of inverter 222 and net 224 is connected to the output of inverter 222. Inverter 226 is connected between net 224 and net 212. In one embodiment, net 224 is connected to the input of inverter 226 and net 212 is connected to the output of inverter 226. An output net 220 is shown after net 212.

During operation of the non-inverting buffer with hysteresis (i.e., FIG. 5), a signal is applied to input node 200. In one embodiment, a rising transition is applied to input node 200. In one embodiment, when a rising transition is applied to input node 200, input node 200 starts at zero voltage, nets 206 and 208 start at VDD. Net 212 also starts at zero voltage and net 224 starts at VDD. Lastly, output 220 starts at zero voltage. In one embodiment, the size ratio of the pfet to nfet in inverter 202 is larger than the size ratio of the pfet to nfet in inverter 204. As a result, the trip point of inverter 202 would be at a higher voltage than the trip point of inverter 204. Consequently, inverter 202 controls the higher-trip point of the inverting buffer with hysteresis depicted in FIG. 5 and inverter 204 controls the lower-trip point.

In one embodiment, the trip point for inverter 202 is a higher voltage than the trip point for inverter 204. When the input node 200 starts to transition, the first voltage that the input signal will reach is the trip point for inverter 204, since inverter 204 is the lower voltage. When the input signal reaches the lower voltage, then the net 208 will transition from one to zero. When the net 208 transitions from one to zero, that will turn off the nfet 210. In this state, both the pfet 210 and the nfet 211 are off. The storage node consisting of inverter 222 and inverter 226 maintains the value of net 212 at zero.

The input signal 200 continues to rise until it hits the trip point of inverter 202. When the voltage on the input node 200 hits the trip point of inverter 202, the net 206 transitions from a one to a zero. The transition of the net 206 from a one to a zero turns the pfet 210 on. As a result, the nfet 211 is off, the pfet 210 is on, and both nets 206 and 208 have transitioned to zero.

In one embodiment, inverter 226 is a weak inverter compared to pfet 210, therefore inverter 226 attempts to drive a zero onto net 212, but since pfet 210 is stronger than inverter 226, the pfet 210 will overdrive the nfet of inverter 226. Ultimately, pfet 210 will transition net 212 from zero to one. The transition of net 212 from a zero to a one causes inverter 222 to change states. The net 224 changes from a one to a zero. As a result, inverter 226 drives a one just like pfet 210 onto net 212. When net 212 transitions, a transition is made to the output 220.

The inverse transition of the input signal produces the compliment of the foregoing procedure. In the inverse transition, the input signal is applied to input node 200 is at VDD, net 206 is at zero, net 208 is at zero, net 212 is at VDD, output 220 is at VDD, and net 224 is at zero. When input node 200 starts a falling transition, the first voltage that the signal encounters is the voltage maintained by the higher voltage threshold inverter 202. When the input signal passes the higher voltage, which causes the net 206 to transition from a zero to one the pfet 210 turns on. As a result, both the nfet 211 and the pfet 210 are off. However, the voltage at net 212 is being held by the storage node, which consists of inverter 222 and inverter 226. The voltage on the input node 200 continues to fall until the voltage hits the trip point (i.e., threshold) of inverter 204, which causes the net 208 to transition from zero to VDD. The transition on net 208 from zero to VDD turns on the nfet 211.

The nfet 211 is stronger than the pfet of inverter 226. As a result, the nfet 211 pulls the voltage of net 212 down to zero, which causes inverter 222 to change states. Net 224 changes from zero to one. As a result, nfet 211 and inverter 226 both drive the same value on net 212. The transition on 212 propagates to the net 220.

Thus, the present invention has been described herein with reference to a particular embodiment for a particular application. Those having ordinary skills in the art and access to the present teachings will recognize additional modifications, applications, and embodiments within the scope thereof.

It is, therefore, intended by the appended claims to cover any and all such applications, modifications, and embodiments within the scope of the present invention.

1. A buffer, comprising:
an input conveying a first signal;
an upper trip circuit coupled to the input and generating a second signal in response to the first signal conveyed by the input;
a lower trip circuit coupled to the input and generating a third signal in response to the first signal;
a net conveying a high voltage signal and a low voltage signal;
a pull-up device coupled between the upper trip circuit and the net, the pull-up device generating the high voltage signal in response to the second signal;
a pull-down device coupled to the lower trip circuit and coupled to the net, the pull-down device generating the low voltage signal in response to the third signal;
a bus holder coupled to the net, the bus holder capable of maintaining the high voltage signal on the net and capable of maintaining the low voltage signal on the net; and
an output coupled to the net, the output processing the high voltage signal and the low voltage signal.

2. A buffer as set forth in claim 1, wherein the first signal is a rising transition.

3. A buffer as set forth in claim 1, wherein the first signal is a falling transition.

4. A buffer as set forth in claim 1, wherein the upper trip circuit is implemented with a CMOS inverter.

5. A buffer as set forth in claim 1, wherein the lower trip circuit is implemented with a CMOS inverter.

6. A buffer as set forth in claim 1, wherein the upper trip circuit is implemented with a CMOS buffer.

7. A buffer as set forth in claim 1, wherein the lower trip circuit is implemented with a CMOS buffer.

8. A buffer as set forth in claim 1, wherein the pull-up device is implemented with a pfet.

9. A buffer as set forth in claim 1, wherein the pull-down device is implemented with an nfet.

10. A buffer as set forth in claim 1, wherein the output is implemented with a CMOS buffer.

11. A buffer as set forth in claim 1, wherein the output is implemented with a CMOS inverter.

12. A buffer as set forth in claim 1, wherein the bus holder is implemented with cross-coupled CMOS inverters.

13. A CMOS buffer, comprising:
an input conveying an input signal;
a first CMOS inverter coupled to the input and generating a first signal in response to the input signal conveyed by the input;
a second CMOS inverter coupled to the input and generating a second signal in response to the input signal;
a pfet coupled to the first CMOS inverter and generating a third signal in response to the second signal generated by the first CMOS inverter;
an nfet coupled to the second CMOS inverter and generating a fourth signal in response to the third signal generated by the second CMOS inverter;
a net coupled to the pfet and coupled to the nfet, the net capable of conveying the third signal and capable of conveying the fourth signal;
a storage node coupled to the net, the storage node capable of maintaining the third signal on the net and capable of maintaining the fourth signal on the net; and
an output coupled to the net, the output processing the third signal and the fourth signal.

14. A buffer as set forth in claim 13, wherein the first CMOS inverter is configured to operate at a first threshold.

15. A buffer as set forth in claim 13, wherein the second CMOS inverter is configured to operate at a threshold.

16. A buffer as set forth in claim 13, wherein the output is implemented with a CMOS buffer.

17. A buffer as set forth in claim 13, wherein the output is implemented with a CMOS inverter.

18. A buffer as set forth in claim 13, wherein the storage node is implemented with cross-coupled CMOS inverters.

19. A buffer as set forth in claim 13, wherein the first CMOS inverter includes a larger trip voltage than the second CMOS inverter.

20. A buffer, comprising:
an input means conveying a first signal;
an upper threshold means coupled to the input means and generating a second signal in response to the first signal hitting an upper threshold;
a lower threshold means coupled to the input means and generating a third signal in response to the first signal hitting a lower threshold;
a means for conveying a signal coupled to the upper threshold means and coupled to the low threshold means, the means for conveying a signal capable of conveying a high voltage signal and capable of conveying a low voltage signal;
a high voltage means coupled to the upper threshold means and coupled to the means for conveying, the high voltage means causing the high voltage signal on the means for conveying a signal; and
a low voltage means coupled to the low threshold means and coupled to the means for conveying a signal, the low voltage means causing the low voltage signal on the means for conveying a signal.
